(19) United States
(12) Patent Application Publication
(10) Pub. No.: US 2025/0089543 A1
(43) Pub. Date: Mar. 13, 2025

(54) PROCESS FOR PRODUCING AN ORGANIC-INORGANIC HYBRID PEROVSKITE LAYER

(71) Applicant: Commissariat à I'Énergie Atomique et aux Énergies Alternatives, Paris (FR)

(72) Inventors: Louis Grenet, Grenoble (FR); Elodie Testard, Grenoble (FR); Frédéric Roux, Grenoble (FR); Solenn Berson, Grenoble (FR); Polyxeni Tsoulka, Grenoble (FR)

(73) Assignee: Commissariat à I'Énergie Atomique et aux Énergies Alternatives, Paris (FR)

(21) Appl. No.: 18/830,043

(22) Filed: Sep. 10, 2024

(30) Foreign Application Priority Data
Sep. 12, 2023 (GR) 20230100731
Oct. 12, 2023 (FR) 2310971

(51) Int. Cl. H10K 71/16; C07F 19/00; H10K 30/30; H10K 30/40; H10K 30/50; H10K 85/50

(52) U.S. Cl. CPC H10K 71/164; C07F 19/005; H10K 30/30; H10K 30/40; H10K 30/50; H10K 85/50

(57) ABSTRACT

A process for producing a layer of organic-inorganic hybrid perovskite material including the following steps: a) Forming of a layer comprising the inorganic precursors of perovskite material on a substrate by CSS or CSVTD, b) Implementation of a CSS or CSVTD step from organic precursors the organic precursors with the layer of inorganic precursors and a layer of organic-inorganic hybrid perovskite material is obtained.

### TECHNICAL FIELD

The present disclosure generally concerns the field of organic-inorganic hybrid perovskites, and more particularly their production process.

The invention has applications in many industrial fields, in particular in photovoltaics, or also for the manufacturing of electronic, optical, or optoelectronic devices, in particular for the manufacturing of light-emitting diodes (LEDs), photodetectors, scintillators, X-ray detectors, for example for medical applications, or also transistors.

The invention is particularly advantageous since it enables to form perovskite layers having a controlled composition with relatively short deposition times, compatible with a large-scale implementation.

### PRIOR ART

Organic-inorganic hybrid perovskites are particularly advantageous materials for photovoltaic cells, and especially for tandem photovoltaic cells on silicon.

Among particularly promising organic-inorganic hybrid materials, there can be mentioned ABX₃-type materials with A representing a cation or a mixture of cations selected from among Cs⁺, FA⁺ (with F=CH₅N₂), MA⁺ (where MA=CH₃—NH₃), B a metal cation selected from among Pb, Sn, Ge, and X a halogen selected from among Cl, Br, and I.

Generally, hybrid perovskite layer production processes are carried out in two steps: the inorganic part of the perovskite is deposited first, after which the organic part is added.

For example, in the article by Zhang et al. (ACS Appl. Energy Mater. 2022, 5, 5797-5803) films of Cs_{0.14}FA_{0.86}Pb (BrₓI₁₋ₓ)₃ are also obtained by implementing a process in two steps. In a first step, inorganic layers of CSI and PbI₂ are sequentially deposited on a substrate. In a second step, an organic FAI film or an organic FAI/FABr film is prepared by depositing on a substrate the organic precursors by the spraying of an ethanol solution comprising said precursors. This film is used to implement a step of close space sublimation (CSS) at a 160° C. temperature. During this step, the material is sublimated, which enables to react the organic vapors with the CSI and PbI₂ layers and thus to form the perovskite material.

However, the described synthesis process here requires a first step of deposition of inorganic precursors, which is generally carried out by liquid deposition or by co-evaporation. In these 2 cases, the inorganic precursor deposition process provides serious obstacles for industrialization, particularly as concerns the production rate, the deposition homogeneity over large surfaces, the possibility of deposition on textured substrates, or also liquid effluent management.

### SUMMARY OF THE INVENTION

There exists a need for a process enabling to form an organic-inorganic hybrid perovskite layer having a controlled composition and enabling to form such a layer on large surfaces (typically larger than 20×20 cm²) and/or on textured substrates (for example for wafers, particularly made of silicon, having at their surface a pyramid texture, having, in particular, a height greater than 1 μm) at a high rate, so that it can be industrialized.

This aim is achieved by a process for producing a layer of organic-inorganic hybrid perovskite material comprising the following steps:
a) Forming of a layer comprising the inorganic precursors of the perovskite material on a substrate by CSS or by CSVTD,
b) Implementation of a CSS or CSVTD step from organic precursors, whereby the organic precursors react with the inorganic precursors present in the layer and a layer of organic-inorganic hybrid perovskite material is obtained.

The invention fundamentally differs from prior art by the implementation of a production process in two steps, where step a) and step b) can be carried out independently of each other by close space sublimation (CSS) or by close spaced vapor transport deposition (CSVTD, also sometimes noted CSVT). CSVTD is also sometimes called short-range chemical vapor transport.

The CSS step consists in sublimating a solid material, the distance between the substrate and the material to be sublimated being short. By short distance, there is meant a distance in the range from 0.1 to 10 mm, preferably from 0.1 to 5 mm.

The CSVTD step consists in sublimating a solid material or evaporating a liquid material. The solid or liquid material is for example placed in a crucible which is heated. This step is also performed at short distance (for example in the order of one millimeter).

CSVTD enables, just like CSS, to have a high deposition speed, a small loss of material, and a high homogeneity of layers.

The first CSS or CSVTD step (step a) enables to form a layer comprising the inorganic precursors of the perovskite material. The second CSS or CSVTD step (step b) enables to impregnate the previously-deposited layer with the organic precursors of the perovskite material. This impregnation results from the reaction of the inorganic precursors with the gaseous phase resulting from the evaporation or from the sublimation of the organic precursors. During step b), the organic precursors are in gaseous form. This impregnation results in the forming of the final material.

These sublimation or evaporation processes are particularly advantageous from an industrial point of view, since they enable to rapidly form layers of perovskite material of controlled composition.

For example, CSS and CSVTD deposition rates may be higher than 100 nm/min or even higher than 1,000 nm/min. As an illustration, evaporation deposition rates are in the order of 10 nm/min.

Advantageously, the organic-inorganic hybrid perovskite has formula A′₁₋ₓAₓBX₃ with:

A′ an inorganic cation or an alloy of inorganic cations, preferably selected from among Cs, Rb, K, and Na,

A a monovalent organic cation or an alloy of monovalent organic cations, preferably selected from among methylammonium (MA), formamidinium (FA), guanidinium (GA), dimethylammonium (DA), and imidazolium (IA), or more preferably A corresponds to MA and/or FA,

B an inorganic cation or an alloy of inorganic cations, preferably selected from among Pb, Sn, and Ge,

X one or a plurality of halogens, preferably selected from among Cl, Br, I, and F.

Advantageously, the organic-inorganic hybrid perovskite has formula Cs₁₋ₓMAₓPb(I_{1-y}Br_{y})₃, Cs₁₋ₓFAₓPb(I_{1-y-z}Br_{y}Cl_{z})₃ or Cs₁₋ₓFAₓPb(I_{1-y}Br_{y})₃, Cs₁₋ₓFAₓPb_{0.5}Sn_{0.5}(I_{1-y}Br_{y})₃, Cs_{1-x-z}MAₓFA_{z}Pb(I_{1-y}Br_{y})₃, or Cs_{1-x-z}MAₓFA_{z}Pb₁₋ₖSnₖI_{1-y}Br_{y})₃ with 0≤y≤1, 0≤k≤1, 0≤x≤1, 0≤z≤1, and 0≤x+z≤1, and preferably 0<y<1 and 0<x<1.

Advantageously, the layer comprising the inorganic precursors is a layer containing Pb, Cs, and one or a plurality of halogens selected from among iodine, bromine, and chlorine. Advantageously, the layer of inorganic precursors is a layer of PbI₂ and CsI, a layer of PbI₂ and CsBr, a layer of PbBr₂ and CsI, a layer of PbBr₂ and CsBr, a layer of PbI₂, PBBr₂, and CSI, a layer of PbI₂, PBBr₂, and CSBr, a layer of PbI₂, CSI, and CsBr, a layer of PbBr₂, CSI, and CsBr, or a layer of PbBr₂, PbI₂, CSI, and CsBr.

Advantageously, the organic precursors are FA(I_{1-y}Br_{y}) or MA(I_{1-y}Br_{y}) with 0≤y≤1 and, preferably, 0<y<1.

According to a first advantageous embodiment, step a) and step b) are carried out by CSS.

According to this first advantageous embodiment, step a) and/or step b) may be carried out by CSS from a precursor powder obtained by mechanosynthesis.

For example, step b) may be carried out by CSS from a powder of organic precursors, the powder of organic precursors is obtained by mechanosynthesis by co-grinding at least a first group of particles made of a first material and a second group of particles made of a second material, until forming a third group of particles of a third material, the third group of particles forming the powder of organic precursors.

Step a) may also be carried out in this way by mechanosynthesis, by co-grinding different groups of particles made of different materials to obtain the powder of inorganic precursors, formed of particles, preferably single-phase, each particle having the composition which is desired to be subsequently reacted with the organic precursors.

According to a second advantageous alternative embodiment, step a) and step b) are carried out by CSVTD.

Advantageously, the substrate is a substrate adapted to photovoltaics. For example, it may be a glass, plastic, or metal substrate.

Advantageously, the substrate is a silicon substrate, preferably a textured silicon substrate. Such a substrate is particularly advantageous to form a photovoltaic device.

The invention also concerns a process for manufacturing a multi-junction photovoltaic cell comprising at least one perovskite photovoltaic cell, or a single-junction perovskite photovoltaic cell, the process comprising the production of an organic-inorganic perovskite layer according to the process such as previously described.

The multi-junction photovoltaic cell comprising at least one perovskite photovoltaic cell is, for example, a perovskite-silicon tandem photovoltaic cell, a perovskite-perovskite tandem photovoltaic cell, a perovskite-perovskite-silicon triple junction photovoltaic cell, or a perovskite-perovskite-perovskite triple junction photovoltaic cell.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIG. 1A and FIG. 1B schematically show different steps of a process for producing an organic-inorganic perovskite layer according to a specific embodiment of the invention;

FIG. 2A and FIG. 2B schematically show various steps of a process for producing an organic-inorganic perovskite layer according to another specific embodiment of the invention;

FIG. 3 schematically shows in cross-section a close space sublimation furnace according to a specific embodiment of the invention;

FIG. 4A and FIG. 4B are simplified and cross-section views, respectively, of a single-junction photovoltaic cell and of a tandem photovoltaic cell, according to different specific embodiments of the invention;

FIG. 5A is an image obtained with a scanning electron microscope of a layer of inorganic precursors obtained according to a specific embodiment of the invention;

FIG. 5B is an image obtained with a scanning electron microscope of an organic-inorganic hybrid perovskite layer obtained from the inorganic precursor layer of FIG. 4A, according to a specific embodiment of the invention;

FIG. 6 is a graph showing an X-ray diffractogram of an organic-inorganic perovskite layer, according to a specific embodiment of the invention;

FIG. 7 is an image obtained with a scanning electron microscope of a perovskite layer deposited on a textured silicon substrate, according to a specific embodiment of the invention;

FIG. 8 is a current-vs.-voltage curve, under an AM1.5 illumination at t=0 and at t=24 h and in the dark, of a photovoltaic cell comprising an organic-inorganic perovskite layer obtained according to a specific embodiment of the invention;

FIG. 9 is a current-voltage curve under an AM1.5 illumination of a photovoltaic cell comprising an organic-inorganic perovskite layer obtained according to another specific embodiment of the invention.

### DESCRIPTION OF EMBODIMENTS

Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as “front”, “back”, “top”, “bottom”, “left”, “right”, etc., or relative position qualifiers, such as “top”, “bottom”, “upper”, “lower”, etc., or orientation qualifiers, such as “horizontal”, “vertical”, etc., reference is made unless otherwise specified to the orientation of the drawings.

Unless specified otherwise, the expressions “about”, “approximately”, “substantially”, and “in the order of” signify plus or minus 10%, preferably of plus or minus 5%.

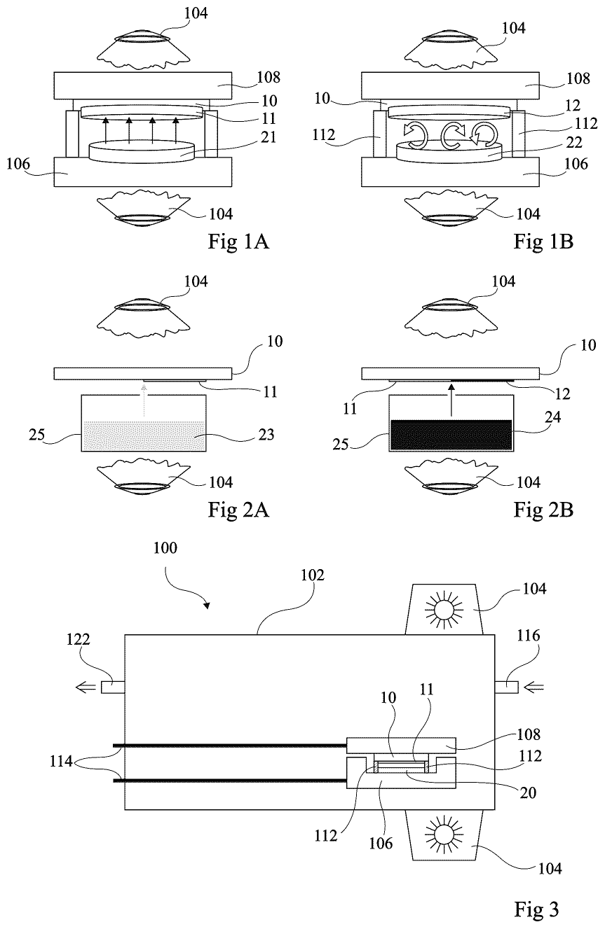

The method which will be described in greater detail hereafter, referring to FIGS. 1A and 1B as well as to FIGS. 2A and 2B, concerns the production of an organic-inorganic hybrid perovskite layer.

The organic-inorganic hybrid perovskite has, preferably, general formula A′₁₋ₓAₓBX₃ with:
A′ an inorganic cation or an alloy of inorganic cations, preferably selected from among Cs⁺, Rb⁺, K⁺, and Na⁺,
A a monovalent organic cation or an alloy of monovalent organic cations, selected from among CH₃NH₃⁺ (methylammonium MA), CH(NH₂)₂⁺ (formamidinium or FA), C(NH₂)₃⁺ (guanidinium or GA), C₂H₈N (dimethylammonium or DA), C₃H₅N₂ (imidazolium or IA); an alloy of monovalent organic cations may be, for example, MA₁₋ₓFAₓ with 0<x<1),
B an inorganic cation or an alloy of inorganic cations, preferably selected from among Pb²⁺, Sn²⁺, and Ge²⁺,
X a halogen anion or anion alloy, preferably selected from among Cl, Br, I, and F.

Preferably, A′ represents Cs.

Preferably, A represents MA and/or FA.

Preferably, B represents Pb, Sn, and Ge,

Preferably, X represents Br and/or I.

Advantageously, the organic-inorganic hybrid perovskite has formula Cs₁₋ₓMAₓPb(I_{1-y}Br_{y})₃, Cs₁₋ₓFAₓPb(I_{1-y-z}Br_{y}Cl_{z})₃ or Cs₁₋ₓFAₓPb(I_{1-y}Br_{y})₃ or Cs₁₋ₓFAₓPb_{0.5}Sn_{0.5}(I_{1-y}Br_{y})₃ or Cs_{1-x-z}MAₓFA_{z}Pb(I_{1-y}Br_{y})₃ or Cs_{1-x-z}MAₓFA_{z}Pb₁₋ₖSnₖI_{1-y}Br_{y})₃ with 0≤y≤1, 0≤k≤1, 0≤x≤1, 0≤z≤1, and 0≤x+z≤1, and preferably 0<y<1 and 0<x<1.

The process comprises the following steps:
a) Forming of a layer 11 on a substrate 10, by CSS or CSVTD, by sublimating or evaporating the inorganic precursors 21, 23 of the perovskite material, whereby a layer 11 comprising, and preferably consisting of, the inorganic precursors is formed (FIGS. 1A or 2A),
b) Sublimation or evaporation, by CSS or CSVTD, of organic precursors 22, 24 of the perovskite material, whereby the organic precursors, in gaseous form, react with the inorganic precursors present in the layer 11 formed at step a) and a layer 12 of hybrid organic-inorganic perovskite material is obtained (FIGS. 2A or 2B).

It is possible to use one of the four alternative embodiments:
implementation of step a) by CSS and implementation of step b) by CSVTD,
implementation of step a) by CSS and implementation of step b) by CSS,
implementation of step a) by CSVTD and implementation of step b) by CSS,
implementation of step a) by CSVTD and implementation of step b) by CSVTD.

In a particularly advantageous variant, step a) and step b) are implemented by CSS (FIGS. 1A and 1B).

In the case of a CSS deposition, precursors 21, 22 are in the solid state, preferably in the form of a powder.

The powder may form a bed of particles.

Alternatively, the particles may be agglomerated to form a solid target (also known as a wafer). The powder may be compacted, for example, by means of a hydraulic press. For this purpose, the powder is pressed, for example with a hydraulic press with P˜1×10⁷ Pa). The pressing of the target may be performed by heating the powder.

The precursor powder 21, 22 used may comprise, for example, a first group of particles made of a first material and a second group of particles made of a second material.

According to an advantageous embodiment, precursor powder 21, 22 is obtained by mechanosynthesis, by co-grinding at least a first group of particles made of a first material and a second group of particles made of a second material, to form a third group of particles of a third material.

The third group of particles forms inorganic precursor powder 21 (step a)) or organic precursor powder 22 (step b)).

Mechanosynthesis consists of performing a high-energy co-grinding of pure or pre-alloyed materials in a high-energy mill until obtaining a powder having single-phase or multi-phase particles. Preferably, the particles are single-phase.

The co-grinding is carried out with at least two groups of particles. It may also be implemented with more than two groups of particles (for example three or four groups of particles).

The co-grinding is carried out in a planetary ball mill. The mass of balls is at least twice greater than the mass of powders, for example at least 15 times greater.

The grinding rotation speed is high (typically from 100 rpm to 700 rpm, for example 500 rpm). It depends on the mill used as well as on the mass of balls and of powders. The grinding time is for example between 10 min and 5 h, for example 1 h.

The mixture may be an equimolar mixture.

This embodiment is particularly advantageous since it enables to directly obtain the right composition and the right phase of the material to be sublimated.

According to another alternative embodiment, to implement step a) and/or step b) by CSS, the precursors may be in the form of a layer previously deposited on another substrate. Such a layer may, for example, be formed by a vacuum deposition process (evaporation or sputtering, in particular) or by a liquid deposition process (for example by spin coating or by slot die coating). It is also possible to form a single crystal of the material to be deposited (wafer, cut ingot, etc.).

During step a) by CSS, the transfer of material between precursors 21 and substrate 10 takes place over a very short distance (between 0.1 and 10 mm, advantageously 5 mm). Precursors 21 are advantageously arranged so as to have the same geometric shape and the same surface area as the substrate 10 on which the precursors are desired to be deposited. Thus, inorganic precursors 21 sublimate and deposit on substrate 10 (arrow in FIG. 1A).

During step b) by CSS, the precursors pass from a solid to a gaseous state (represented by arrows in FIG. 1B). Precursors 22 may thus be shaped into a shape that may be identical to or different from that of the substrate 10 covered with the layer 11 of inorganic precursors.

During step b) by CSS, only the composition of the target matters. Advantageously, the composition of the target may be identical to the composition of the gaseous phase which is desired to be reacted with the layer of inorganic precursors (case of a single-phase target). CSS steps a) and b) may be carried out in a close space sublimation furnace.

A lamp furnace may be used to carry out these steps.

For example, as shown in FIGS. 1A, 1B and particularly detailed in FIG. 3, CSS 100 furnace comprises a reactor 102 around which is positioned a heating system. For example, it may be lamps 104 or any other heating system (resistor, induction, etc.).

Reactor 102 may be made of quartz, of graphite, or of metal.

Reactor 102 may be tubular.

Furnace 100 also comprises a susceptor 106 (also known as a source block) and a cover 108 (also known as a substrate block). Susceptor 106 and cover 108 are made of thermally-conductive materials, capable of withstanding pressure, vacuum, and high temperatures. They are preferably made of graphite.

Substrate 10 and precursors 21, 22 are positioned between susceptor 106 and cover 108.

Preferably, substrate 10 is in direct contact with cover 108, which maintains its temperature at the set point value.

Precursors 21, 22 are placed on susceptor 106.

Substrate 10 is at a short distance from precursors 21, 22. By short distance, there is meant a distance typically from 0.05 mm to 20 mm, or even from 0.1 to 20 mm, preferably from 1 mm to 7 mm, for example from 1 mm to 5 mm or from 3 mm to 5 mm for step a) and preferably from 0.1 mm to 5 mm for step b). In particular, a 1-mm or 5-mm distance may be selected. A compromise will be chosen between a distance sufficiently close to have a high deposition speed and a distance sufficient to be able to maximize and to maintain the thermal gradient during the deposition.

One or a plurality of spacers 112, which may be made of a thermally-insulating material (for example glass, quartz, or alumina), are used to keep substrate 10 at a short distance from powder 20.

Cover 108 may be kept pressed against substrate 10 by a fastening system in susceptor 106 not shown (for example a screw or any other fastening system).

Susceptor 106 and cover 108 each have a thermocouple 114 or any other system (pyrometer, etc.) for measuring and controlling their temperature.

A heating system (lamp, resistors, induction, etc.) enables to regulate the temperature of susceptor 106 (Ttarget) and of cover 108 (Tsubstrate) within a range capable of spanning from 20° C. to 600° C. Temperature rise ramps may be controlled in a range, for example, from 0.1° C./s to 10° C./s. Susceptor 106 (Ttarget) and cover 108 (Tsubstrate) may be controlled by temperature ramps (or sequences of ramps), in independent manner. Thus, it is possible to adjust the sublimation kinetics of powder 20 and the reaction temperatures with the inorganic layer deposited on substrate 10 to control the morphology of the layer and/or the duration of the process.

It is possible to add specific cooling devices for cover 108 (for example, integrated coolant piping, susceptor radiation shield, radiators).

Device 100 is coupled to an inlet for inert gas 116 (such as argon or N₂).

Device 100 may also be coupled to an inlet for oxidizing gas (such as O₂) or to an inlet for reducing gas (such as H₂).

Device 100 comprises a gas outlet 122, coupled to a pumping system enabling to achieve a vacuum Pfurnace ranging, for example, from 0.00001 Pa to 1 Pa. value Pfurnace depends on the CSS furnace used.

The sublimation deposition is performed by heating susceptor 106 and cover 108 under vacuum (typically between 0.01 and 100 Pa, for example 1 Pa), to sublimate the organic or inorganic precursors.

In the case of step a) of the deposition by CSS, the temperature Tsub of substrate is lower than target temperature Ttarget to create a thermal gradient. The substrate is advantageously maintained at a controlled temperature. The same applies to the target.

In the case of step a) of the deposition by CSS, temperature difference Ttarget−Tsub is from 10° C. to 350° C., preferably from 50° C. to 300° C., and even more preferably from 50° C. to 200° C., for example 100° C.

During step b), the target temperature may be identical to the substrate temperature.

According to an alternative embodiment, during step b), substrate temperature Tsub is advantageously lower than target temperature Ttarget, to create a thermal gradient while promoting a higher partial pressure of the organic compound without risking decomposing the perovskite. Temperature difference Ttarget−Tsub is from 1° C. to 350° C. (for example from 1 to 100° C., in particular 20° C.), preferably from 50° C. to 300° C. and even more preferably from 100° C. to 250° C., for example 150° C.

According to another alternative embodiment, during step b), Ttarget<Tsubstrate to promote vapor condensation on the substrate and thus accelerate the reaction. The temperature difference may be from 1 to 100° C., for example 20° C.

The targeted temperatures depend on the material to be sublimated.

Temperature rise ramps in the range from 0.2° C./s to 10° C./s, for example, of 1° C./s, may for example be performed.

According to another particularly advantageous variant, step a) and step b) are implemented by CSVTD (FIGS. 2A and 2B).

As shown in FIGS. 2A and 2B, in the case of a CSVTD step, precursors 23, 24 may be positioned in a crucible 25. Substrate 10 is positioned opposite crucible 25. It is also possible to displace substrate 10 relative to crucible 25.

The use of crucibles enables to envisage heating the inorganic or organic precursors up to their melting temperature, or even beyond their melting temperature, to accelerate material flows (deposition rate of inorganic precursors or partial pressure of the organic part).

The CSVTD reactor is, for example, a quartz tube. The heating system may be equipped with lamps 104 or also with a heating resistor.

Substrate 10 and crucible 25 may be heated independently of each other by lamps or any other heating system (for example a resistor).

Precursors 23, 24 may be in the liquid or solid state. Thus, according to the state of the precursor (liquid or solid), the CSVTD step may be implemented by evaporation or by sublimation, respectively.

When the precursors are in solid form, they may be in the form of powders obtained by mechanosynthesis.

The implementation of a CSVTD enables either to form a layer 11 on substrate 10 from inorganic precursors 23 (step a)) or to react organic precursor vapors 24 with inorganic precursor layer 11 to form perovskite layer 12 (step b)).

The temperature of substrate Tsub implemented in the process (that is, during step a) and/or step b)) are, advantageously, lower than 250° C. and more advantageously still lower than 200° C.

In the various previously-described embodiments, the deposition chamber used for step a) and the deposition chamber used for step b) may be identical or different.

Advantageously, different chambers are used and the process is carried out continuously by implementing step a) in a first chamber and step b) in a second chamber.

The implementation of a CSS or CSVTD step allows a displacement of substrate from one chamber to the other to be successively in contact with the inorganic precursors and then with the organic precursors.

The nature of the substrate is closely linked to the targeted application. The substrate may be a glass, polymer (polyimide, for example), or steel substrate. Preferably, it is made of silicon. The silicon substrate may be textured or non-textured. It may also be polished.

Advantageously, the substrate is functionalized with a layer or a stack of insulating, conducting, and/or semiconductor layers to inject and/or collect charges in the perovskite material.

The layers obtained by such a process are homogeneous and continuous.

Preferably, inorganic precursors 21, 23 are selected from among the following materials: CsCl, CsBr, CsI, PbCl₂, PbBr₂, and PbI₂, preferably with at least one Cs halide and one Pb halide. It may be a combination of two, three, or more than three precursors.

For example, inorganic precursors 21, 23 are selected from one of the following combinations: a combination of two materials such as PbI₂ and CsI, PbI₂ and CsBr, PbBr₂ and CsI, PbBr₂ and CsBr, or also a combination of three materials PbI₂, PBBr₂ and CsI or PbI₂, PBBr₂ and CsBr or PbI₂, CSI and CsBr or PbBr₂, CSI and CsBr or PbBr₂, PbI₂, CSI and CsBr. Preferably, it is PbI₂ and CsBr.

For example, organic precursors 22, 24 are FA(I_{1-y}Br_{y}) or MA(I_{1-y}Br_{y}) with 0<y<1. Such precursors can be obtained, for example, by mechanosynthesis from FABr and FAI powders or from MABr and MAI powders. Organic precursors MA(I_{1-y}Br_{y}) may be used to form layers of Cs₁₋ₓMAₓPb(I_{1-y}Br_{y})₃. Organic precursors FA(I_{1-y}Br_{y}) may be used to form layers 12 of Cs₁₋ₓFAₓPb(I_{1-y}Br_{y})₃.

According to another example, organic precursors 22, 24 may be MA_{z}FA_{1-z}I_{1-y}Br_{y} (with 0<z<1 and 0<y<1). They may be obtained by mechanosynthesis from MABr and/or MAI and/or FABr and/or FAI powders. These precursors may be used to form layers 12 of CsₓMA_{z}FA_{1-z-x}Pb(I_{1-y}Br_{y})₃.

According to another example, organic precursors 22, 24 are FAI_{1-y-z}Br_{y}Cl_{z} (with 0<y<1 and 0<z<1). They can be obtained from FAI and/or FABr and/or FACI powders. They may be used to form layers 12 of Cs₁₋ₓFAₓPb(I_{1-y-z}Br_{y}Cl_{z})₃.

The obtained perovskite layers may be used in many industrial fields, in particular in the field of X-ray detection for medical applications, safety, security, radiation protection, and large-scale scientific instruments, but also in photovoltaics, gamma radiation detection, ionizing radiation (alpha, beta, neutron), or also for the manufacturing of electronic, optical, or optoelectronic devices, in particular for the manufacturing of light-emitting diodes (LEDs), photodetectors, scintillators, or also transistors.

In particular, the process applies to deposit organic-inorganic hybrid perovskites of low thicknesses (in the range from 10 nm to 5,000 nm). These materials are generally used for visible or near-infrared optical applications. Photovoltaic applications, but also infrared and near-infrared detection or light emission in the visible, near-infrared and infrared wavelengths, will in particular be mentioned.

In particular, as concerns photovoltaic applications, the previously-described process may be used to produce a layer of organic-inorganic hybrid perovskite material in a photovoltaic cell.

By adjusting the amount of iodine, of bromine, and of chlorine in the perovskite material, it is possible to modify the bandgap energy.

Photovoltaic cells may be single-junction cells or multi-junction cells.

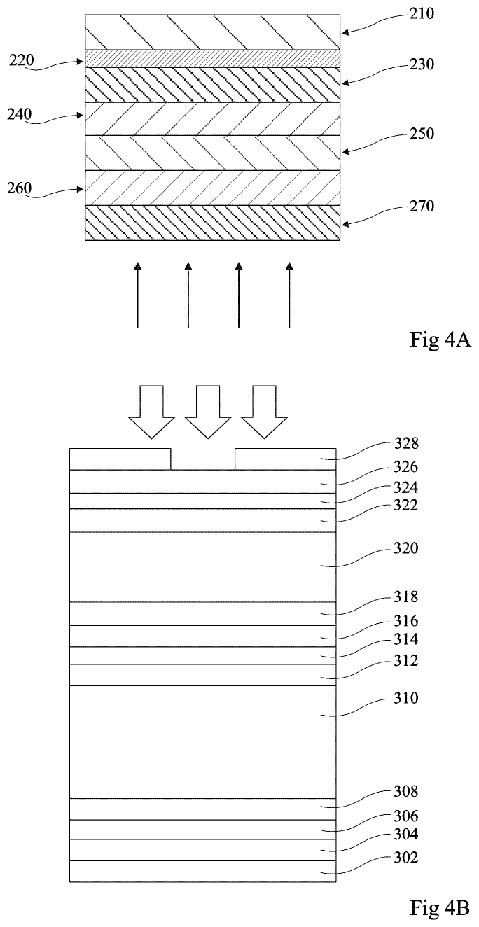

For example, a single-junction photovoltaic cell of p-i-n type may comprise, from the back side to the front side (FIG. 4A):
an upper electrode 210,
a buffer layer 220,
an n-type layer 230,
a perovskite active layer 240,
a p-type layer 250,
a transparent conductive oxide layer 260,
a substrate 270.

Preferably, the photovoltaic cell is formed of the various elements mentioned hereabove.

The front surface of the photovoltaic cell is intended to receive a luminous flux.

The incident radiation is represented by arrows in FIG. 4A.

Upper electrode 210 is, for example, made of Ag, Cu, Ni, Al. It has, for example, a thickness in the range from 50 to 300 nm.

Buffer layer 220 has a thickness in the range from 1 nm to 5 nm, preferably from 3 to 4 nm. It is advantageously continuous and conformal. It is in direct contact with the n-type layer.

It may be a layer of LiF, SnS, metal oxide, BCP (bathocuproine), or also of alumina of formula Al₂O₃ or of formula AlOx with x in the range from 0.8 to 1.5.

N-type 230 layer may be, for example, made of C60, PC61BM ([6,6]-phenyl-C61-methyl butanoate or “[6,6]-phenyl-C61-butyric acid methyl ester”), PC71BM ([6,6]-phenyl-C71-methyl butanoate or “[6,6]-phenyl-C71-butyric acid methyl ester”), PCBM/C60, or PCBM/C. Preferably, it is made of C60. N-type layer 230 for example has a thickness in the range from 5 to 50 nm.

According to other alternative embodiments, n-type layer 230 may be an oxide layer, for example SnOx (with x in the range from 1 to 2), ZnO, Al:ZnO, ITO, or IZO.

Such layers have a thickness in the range from 5 to 30 nm.

Active layer 240 is an active perovskite layer obtained by the previously-described process. Preferably, the perovskite layer is a perovskite of APbX₃ type, with A representing methylammonium, dimethylammonium, formamidinium, guanidinium, or cesium cations (the above-mentioned cations may be used alone or in a mixture) and X representing halide anions (preferably chlorine, bromine, or iodine anions, alone or in a mixture).

Active layer 240 has, for example, a thickness in the range from 200 nm to 1.5 μm.

According to a first variant, p-type layer 250 may be a layer of poly(3,4-ethylenedioxythiophene) (PEDOT) or poly[bis(4-phenyl)(2,4,6-trimethylphenyl)amine (PTAA)]. It may have a thickness in the range from 5 to 50 nm.

According to a second variant, p-type layer 250 is a self-assembled monolayer (SAM). The SAM layer may be a layer of 2PACz (2-(9H-Carbazol-9-yl)ethyl]phosphonic acid), 3PACz (3-(9H-carbazol-9-yl)propyl)phosphonic acid), 4PACz (4-(9H-carbazol-9-yl)butyl)phosphonic acid), Me-4PACz (4-(3,6-Dimethyl-9H-carbazol-9-yl)butyl)phosphonic acid), MeO-2PACz (2-(3,6-Dimethoxy-9H-carbazol-9-yl)ethyl)phosphonic acid), 6dPA (1,6-hexylenediphosphonic acid), or also a layer of MPA (methylphosphonic acid), or a layer obtained from a mixture of these molecules. It may also be one of their derivatives. Additives may also be added. The molecules of the SAM layer advantageously have a function enabling to anchor to the underlying oxide layer. Such a p-type layer 250 may have a thickness in the range from 1 to 5 nm.

According to a third variant, p-type layer 250 is an oxide layer, for example a MoOₓlayer (for example having a thickness between 5 and 30 nm), a NiOₓ layer (for example having a thickness between 1 and 30 nm).

According to another variant, p-type layer 250 may be an oxide/SAM bilayer, for example a NiOₓ/SAM bilayer.

Transparent conductive oxide layer 260 has, for example, a thickness in the range from 50 to 300 nm. Preferably, it is indium tin oxide (or ITO).

These various elements are positioned on a substrate 270 arranged on the back side. Substrate 270 is for example made of glass.

For example, the photovoltaic cell comprises from the back side to the front side:
an upper silver electrode 210,
an alumina buffer layer 220,
an n-type layer 230 made of C60,
an active layer 240 made of (FA_{0.83}Cs_{0.17})Pb(I_{0.6}Br_{0.4})₃,
an n-type 250 layer made of 2PACz,
a transparent conductive oxide layer 260 made of ITO,
a substrate, preferably made of glass 270.

For example, a tandem photovoltaic cell may comprise a lower sub-cell made of silicon (Si) and an upper sub-cell made of perovskite (PK).

Such a cell is for example shown in FIG. 4B. This structure is known as of “reverse” or p-i-n type. The cell comprises, from the front side to the back side:
a first electrode 302,
a first transparent conductive oxide layer 304, for example made of ITO or AZO,
a layer of p-doped amorphous silicon 306,
optionally, an intrinsic amorphous silicon layer 308,
an active crystalline silicon layer 310,
optionally, an intrinsic amorphous silicon layer 312,
an n-doped amorphous silicon layer 314,
a second transparent conductive oxide layer 316, for example made of ITO or AZO,
a p-type layer (HTL) 318, for example made of PEDOT, PTAA, or also of an oxide (MoOₓ or NiOₓ for example) or formed of an SAM,
an active layer of perovskite 320, for example of formula APbX₃,
a passivation layer, for example MgFx, AlOx, LiF,
an n-type layer (ETL) 322, for example made of C₆₀,
a buffer layer 324, for example made of BCP or of an oxide such as SnOₓ,
a third layer of transparent conductive oxide 326, for example made of ITO or AZO,
a second electrode 328, for example made of Ag, Cu, Ni, or Al.

The various materials used for the upper sub-cell made of perovskite (PK) may for example be selected from among the materials previously described for the single-junction cell.

The CSS deposition process is particularly adapted to forming perovskite-based solar cells on a Si bottom cell. The bottom cell may have a textured surface (for example a pyramid-shaped surface with a height from 1 to 2 μm). In the case of tandem cells on Si, it may in particular be the Cs₁₋ₓFAₓPb(I_{1-y}Br_{y})₃ perovskite with 0.65<x<0.9 (preferably x˜0.8) and y˜0.3. The Br content can be easily adjusted to obtain an energy bandgap at 1.7 eV (that is, 0.2<y<0.4).

For photovoltaic applications, the perovskite layer production process may also be used to manufacture single-junction solar cells based on perovskite. In this case, the perovskite will have a bandgap energy in the range from 1.3 eV to 1.5 eV. It may in particular be the Cs₁₋ₓFAₓPb(I_{1-y}Br_{y})₃ perovskite with x˜0.85 and 0.05<y<0.25.

It is also possible to manufacture a tandem perovskite (1.2 eV)/perovskite (1.8 eV) cell by depositing a first Cs₁₋ₓFAₓPb_{0.5}Sn_{0.5}(I_{1-y}Br_{y})₃ perovskite with x˜0.85 and y˜0.05 and a second Cs₁₋ₓFAₓPb(I_{1-y}Br_{y})₃ perovskite with x˜0.85 and y˜0.5. One of the perovskite layers or both perovskite layers may be formed according to the previously-described process.

Various embodiments and variants have been described. Those skilled in the art will understand that certain features of these various embodiments and variants may be combined, and other variants will occur to those skilled in the art.

Finally, the practical implementation of the described embodiments and variants is within the abilities of those skilled in the art based on the functional indications given hereabove.

### Illustrative and non-limiting example of a specific embodiment of the invention

In this example, an organic-inorganic hybrid perovskite layer of formula CsₓFA₁₋ₓPb(I_{1-y}Br_{y})₃ with x˜0.8 and y˜0.2 has been produced. The layer has a 300-nm thickness.

Preparation of the first target for the first CCS deposition step and deposition of the inorganic precursors from this first target.

The first target is manufactured from Pb and Cs precursors. In particular, the precursors are Pb and Cs halides, selected from among PbI₂ and PbBr₂, on the one hand, and CsI and CsBr on the other hand.

The powder is compacted by means a hydraulic press (P˜1×10⁷ Pa). It forms a solid wafer having lateral dimensions identical to those of the deposit which is desired to be formed. It has a thickness of approximately 0.5 mm. The mass of the powder to manufacture the target is calculated from its dimensions, the density of the powder, and the compactness of the wafer (approximately 0.8 for this pressure value).

For example, for a 3-cm² PbI₂+40 at % CsBr target, approximately 0.4 g of powder will be used.

It is also possible to obtain a powder formed of particles, of a same material, by performing a co-grinding of PbI₂ and of CsBr. A very homogeneous mixture is thus obtained. This step is optional.

For example, the powder may be produced by co-grinding, in a planetary mill for 1 hour at 500 rpm under a neutral atmosphere (Ar or N₂), the PbI₂ with 40 at % of CsBr. This grinding is performed in a tungsten carbide bowl with tungsten carbide balls and a m_{powder}/m_{ball} mass ratio<0.2.

The deposition of the inorganic precursors is performed by CSS from the first target.

The CSS deposition may be performed in an anneal furnace in which the substrate on which the deposition is to be performed is placed opposite the target of the material which is desired to be deposited.

The substrate here is a silicon heterojunction solar cell which has a textured surface covered with an ITO electrode and a with SAM (“Self-Assembled Monolayer”) charge injection layer.

The substrate is placed at a short distance from the target. Typically, a short distance is a distance in the range from 0.1 to 10 mm. For example, a distance of approximately 5 mm is selected.

The assembly is under vacuum, typically the pressure may be in the range from 0.01Pa to 100 Pa. For example, the pressure is 1 Pa.

A heating system enables to independently heat the target and the substrate. The target is heated to a temperature sufficient for it to sublimate and below its melting temperature. The substrate is heated to a temperature lower than that of the target (from 10° C. to 300° C. lower, typically by 100° C.).

The heating system is provided by a graphite susceptor and a graphite cover, against which the target and substrate, respectively, are pressed to ensure their thermalization. The retained heating system is a lamp system. Any other heating system (resistive or induction heating) for heating a susceptor/cover system made of thermally-conductive material (graphite or other), or a system directly heating the target and the substrate by controlling their temperature can be envisaged.

The target material sublimates and condenses on the substrate.

The deposition time and the temperatures condition the thickness of the deposit.

The thickness of the final perovskite is a function of the thickness of the layer of inorganic precursors deposited by CSS.

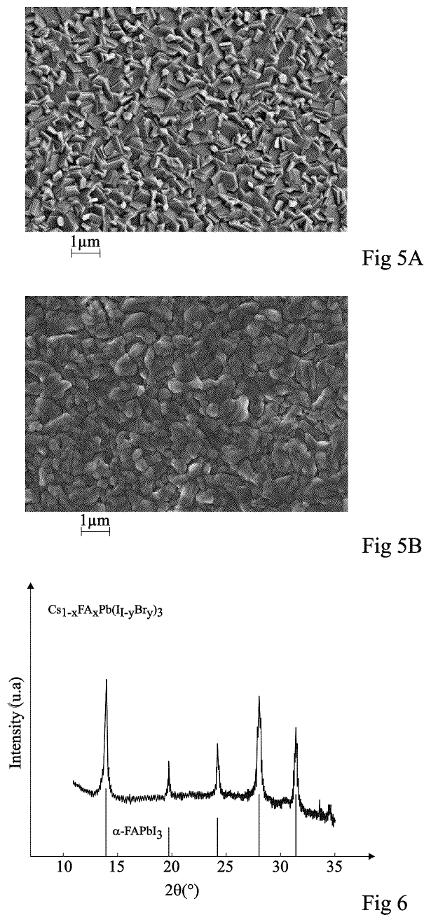

For example, to synthesize a perovskite layer with a 300-nm thickness, a layer of inorganic precursors (from a target of PbI₂+40 at % CsBr) of approximately 250 nm may be deposited (FIG. 5A). The target may be, for example, heated to 270° C. and the substrate to 170° C. for a 5-min period.

The target substrate distance is 5 mm and the pressure is 1 Pa.

Preparation of the second target for the second CCS deposition step and forming of the perovskite layer from this second target.

This second deposition will enable to transform the inorganic precursors into perovskite. The second target for the CSS deposition thus provides the organic components of the perovskite. In this case, these are FA (CH₅N₂) or MA (CH₃NH₃).

The second target comprises FA halides. The target is a solid target, obtained from a compacted powder of FAI 50 at %+FABr 50 at %. The conditions to manufacture the second solid target are identical to those used to manufacture the first target.

The type of CSS equipment used is the same as that used for the first deposition. The substrate comprising the inorganic precursors is positioned opposite and at a short distance from the CSS target, under vacuum.

This step is not a deposition step: its purpose is not to transfer material from the target to the substrate, but it is rather a step of annealing of the precursors present on the substrate under an atmosphere generated by the sublimation of the second target. Accordingly, the target and substrate may be maintained at the same temperature or at different temperatures.

For a given temperature, the duration of this step is adjusted so that all the precursors present on the substrate have reacted. It will be ascertained not to exceed this duration, as this may lead to degrading the perovskite (over-reaction).

For example, for a 250-nm precursor layer containing PbI₂ and 40 at % CsBr, and a solid target comprising FAI 50 at % and FABr 50 at %, the target and substrate are heated to 140° C. for a 15-min period for a target-to-substrate distance of 5 mm and under a 1-Pa pressure. The obtained perovskite layer is shown in FIG. 5B.

The perovskite layer was characterized by X-ray diffraction (FIG. 6). The perovskite layer effectively corresponds to the Cs₁₋ₓFAₓPb(I_{1-y}Br_{y})₃ material with x˜0.9 and y˜0.2.

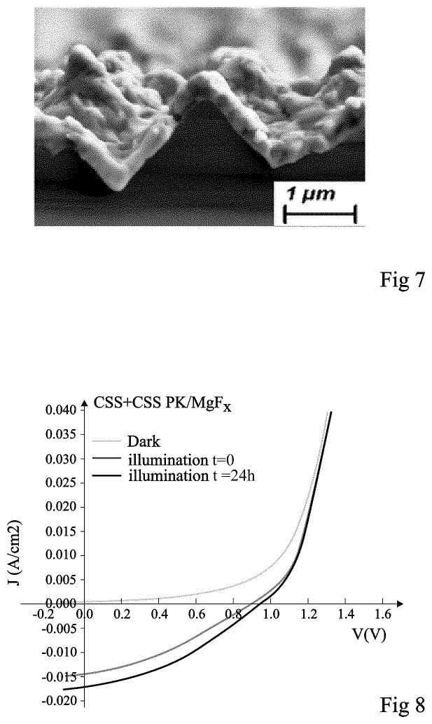

A cross-sectional observation (FIG. 7) confirms that, even for a textured substrate, the obtained layer is conformal and continuous.

The resulting photovoltaic cell was tested by means of a current-vs.-voltage curve in the dark under an AM1.5 illumination at t=0 and t=24 h (FIG. 8). The photovoltaic cell comprising a perovskite layer obtained with such a process has good properties.

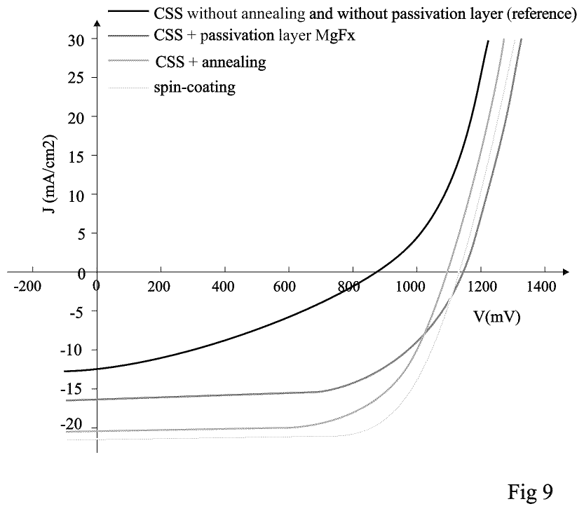

The influence of the presence of an MgFx passivation layer and of a thermal anneal at 150° C. for 20 min in air in a single-junction cell was also studied (FIG. 9). The organic-inorganic perovskite layer is produced with the previously-described process in two steps (curve noted CSS+anneal). The obtained photovoltaic cell has a very good performance. This performance is comparable to that obtained for a photovoltaic cell comprising an organic-inorganic perovskite layer prepared by spin-coating (‘spin-coating’ curve). Spin coating is a deposition technique which is difficult to industrialize for such applications. Its replacement by successive CSS/CSVTD depositions is thus particularly advantageous.

1. Process for producing a layer of organic-inorganic hybrid perovskite material comprising the following steps:
a) Forming of a layer comprising the inorganic precursors of the perovskite material on a substrate by CSS or CSVTD,
b) Implementation of a CSS or CSVTD step from organic precursors, whereby the organic precursors react with the layer of inorganic precursors and a layer of organic-inorganic hybrid perovskite material is obtained.

2. Process according to claim 1, wherein the organic-inorganic hybrid perovskite has formula A′₁₋ₓAₓBX₃ with:
A′ an inorganic cation or an alloy of inorganic cations, selected from among Cs, Rb, K, and Na,
A is a monovalent organic cation or an alloy of monovalent organic cations, preferably selected from among methylammonium, formamidinium, guanidinium, dimethylammonium, and imidazolium, even more preferably A corresponds to MA and/or FA,
B an inorganic cation or an alloy of inorganic cations selected from among Pb, Sn, and Ge,
X one or a plurality of halogens selected from among Cl, Br, I, and F.

3. Process according to claim 1, wherein the organic-inorganic hybrid perovskite has formula Cs₁₋ₓMAₓPb(I_{1-y}Br_{y})₃, Cs₁₋ₓFAₓPb(I_{1-y-z}Br_{y}Cl_{z})₃,Cs₁₋ₓFAₓPb(I_{1-y}Br_{y})₃, Cs₁₋ₓFAₓPb_{0.5}Sn_{0.5}(I_{1-y}Br_{y})₃, Cs_{1-x-z}MAₓFA_{z}Pb(I_{1-y}Br_{y})₃, or Cs_{1-x-z}MAₓFA_{z}Pb₁₋ₖSnₖ(I_{1-y}Br_{y})₃ with 0≤y≤1, 0≤k≤1, 0≤x≤1, 0≤z≤1, and 0≤x+z≤1.

4. Process according to claim 1, wherein the layer comprising the inorganic precursors is a layer containing Pb, Cs, and one or a plurality of halogens selected from among iodine, bromine, and chlorine.

5. Process according to claim 1, wherein the organic precursors are FA(I_{1-y}Br_{y}) or MA(I_{1-y}Br_{y}) with 0<y<1.

6. Process according to claim 1, wherein step a) and step b) are carried out by CSS.

7. Process according to claim 1, wherein step b) is carried out by CSS from a powder of organic precursors, the powder of organic precursors being obtained by mechanosynthesis by co-grinding at least a first group of particles made of a first material and a second group of particles made of a second material, until a third group of particles of a third material is formed, the third group of particles forming the powder of organic precursors.

8. Process according to claim 1, wherein step a) and step b) are carried out by CSVTD.

9. Process according to claim 1, wherein the substrate is a glass, plastic, metal, or silicon substrate, preferably a textured silicon substrate.

10. Process for manufacturing a single-junction perovskite photovoltaic cell or a multi-junction photovoltaic cell comprising at least one perovskite photovoltaic cell, for example a perovskite-silicon tandem photovoltaic cell, a perovskite-perovskite tandem photovoltaic cell, a perovskite-perovskite-silicon triple junction photovoltaic cell, or a perovskite-perovskite-perovskite triple junction photovoltaic cell, the process comprising the production of an organic-inorganic perovskite layer according to the process of claim 1.
